(19) United States
(12) Patent Application Publication
(10) Pub. No.: US 2024/0240354 A1
(43) Pub. Date: Jul. 18, 2024

(54) Method of Growing Personalized Single Crystal Diamond

(71) Applicant: Plasmability, LLC, Austin, TX (US)

(72) Inventors: Robert J. Basnett, Austin, TX (US); William Holber, Winchester, MA (US)

(73) Assignee: Plasmability, LLC, Austin, TX (US)

(21) Appl. No.: 18/412,905

(22) Filed: Jan. 15, 2024

Related U.S. Application Data
(60) Provisional application No. 63/480,155, filed on Jan. 17, 2023.

(51) Int. Cl. C30B 25/20; C30B 25/10; C30B 25/18; C30B 29/04

(52) U.S. Cl. CPC C30B 25/20; C30B 25/10; C30B 25/186; C30B 29/04

(57) ABSTRACT

A method of growing personalized single crystal diamond includes providing a seed diamond material. Diamond is grown on the seed diamond material to a mass of greater than 0.1 gram with an initial finished surface. A process gas is provided that contains at least some carbon from a deceased or living being or inanimate object. A thin film of diamond is grown on top of the initial finished surface to form a second finished surface by using chemical vapor deposition with the process gas.

### CROSS-REFERENCE TO RELATED APPLICATION

The present application is non-provisional of U.S. Provisional Patent Application No. 63/480,155 entitled “Method of Growing Personalized Single Crystal Diamond”, filed on Jan. 17, 2023. The entire contents of U.S. Provisional Patent Application No. 63/480,155 are herein incorporated by reference.

The section headings used herein are for organizational purposes only and should not be construed as limiting the subject matter described in the present application in any way.

### INTRODUCTION

The market for synthetic lab-grown diamond is growing rapidly. This is due, at least in part, to the many desirable material properties of diamond, such as excellent hardness, chemical stability, low-thermal expansion, high thermal conductivity, wide electronic bandgap and broad optical transmission. Grown diamond material is currently used in numerous and growing numbers of applications including, for example, abrasives, electronics, optics, experimental physics, and gems. Lab grown diamond technology has been steadily advancing for the last several decades. The technology has now been widely commercialized and represents a growing portion of the market compared with naturally occurring diamond. One market that has been very rapidly growing is the jewelry market because the optical quality of lab-grown diamond is now so good that it even compares to naturally occurring diamond.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The person skilled in the art will understand that the drawings, described below, are for illustration purposes only. The drawings are not necessarily to scale; emphasis instead generally being placed upon illustrating principles of the teaching. The drawings are not intended to limit the scope of the Applicants' teaching in any way.

FIG. 1 illustrates a flow chart of a method of growing personalized diamond gems by chemical vapor deposition.

FIG. 2 illustrates a flow chart of another method of growing personalized diamond gems by chemical vapor deposition.

### Description of Various Embodiments

The present teaching will now be described in more detail with reference to exemplary embodiments thereof, as shown in the accompanying drawings. While the present teaching is described in conjunction with various embodiments and examples, it is not intended that the present teaching be limited to such embodiments. On the contrary, the present teaching encompasses various alternatives, modifications, and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

It should be understood that the individual steps of the methods of the present teaching may be performed in any order and/or simultaneously as long as the teaching remains operable. Furthermore, it should be understood that the apparatus and methods of the present teaching can include any number or all of the described embodiments as long as the teaching remains operable.

The present teaching relates to synthetic lab-grown single crystal diamond and method of making such diamonds. Synthetic diamond materials have been produced in laboratories for many years by a variety of means. Lab-grown diamond is the common terminology for diamond material made in a fabrication facility rather than dug out of the ground. There are a few common methods by which lab-grown diamonds are made.

One early method of growing diamond is the High-Pressure High Temperature (HPHT) method that uses a starting piece of diamond, which is typically referred to as a seed. This method exposes the seed to extremely high temperature and pressure in the presence of carbon and certain catalytic material. More specifically, in the HPHT process, diamond seed material is placed in a specially designed press, which will allow the growth region to be heated to approximately 2300-1600 degrees C. at pressures exceeding 800,000 pounds per square inch. A carbon starting material dissolves in a metallic catalyst that forms on the starting seed material.

Another early method of growing diamond uses a seed diamond with heated metal filaments in a high temperature reactor. This method is sometimes called the hot filament (HF) method. In the HF process, hot filaments, typically constructed of tungsten, are used to dissociate the gas mixtures, which typically comprise hydrogen and a hydrocarbon gas such as methane, so that carbon-containing species can deposit on the starting substrates, resulting in diamond growth.

Beginning in the 1980's, investigators began looking at plasma chemical vapor deposition (CVD) techniques to form synthetic diamond films. The CVD method also uses a seed diamond that is placed in a vacuum vessel at high temperature in the presence of a plasma discharge formed of hydrogen, carbon-containing gases, and smaller amounts of other gases. The plasma discharge is typically formed using a microwave-based reactor operating in the general pressure range of 10-300 Torr. The temperature of seed material is typically elevated to a temperature that is in the range of 600-1400 degrees C. The exposure of the seed material to reactive species in the plasma enables growth of diamond material on the surface. In some applications, use of a seed diamond is not necessary. For example, in growing polycrystalline diamond material on substrates such as molybdenum or silicon or tungsten, a seed diamond is not needed. As another example, in growing single crystal diamond material on surfaces comprised of iridium or other materials which are closely lattice-matched to diamond, a seed diamond is not needed.

The diamond material grown in the plasma CVD system may be single crystal diamond, polycrystalline diamond, nanocrystalline diamond, diamond-like carbon or combinations of such materials. Applications are wide-ranging and including cutting tools, gems, optics, windows, orifices, electronic materials, sensors, heatsinks, detectors, wear coatings and many other. Other carbon-based materials such as graphene and carbon nanotubes may also be grown in the system.

More specifically, the plasma chemistry for depositing diamond by CVD includes mainly hydrogen chemistry with the addition of a small amount of a carbon-containing gas, such as methane or acetylene. Gases containing one or more dopant material, such as boron, oxygen, argon or nitrogen can also be added in combination with other gases. The plasma dissociates some fraction of the hydrogen as well as the carbon-containing species. Atomic hydrogen adsorbs onto the growing diamond surface and also preferentially etches away non-diamond carbon-bonds in favor of diamond bonds. The highest quality lab grown diamond is almost indistinguishable by experts from naturally forming diamond in optical and mechanical properties.

In order to achieve relatively high growth rate diamond deposition, it is necessary for the plasma discharge to be of sufficient intensity such that the gas in the core of the discharge is heated to greater than 2,000 degrees C. The high gas temperature is necessary in order to maintain a high degree of dissociation of the hydrogen gas into atomic hydrogen, which is critical to the growth of high-quality material at high rates. The conditions that will generate these high gas temperatures are typically total gas pressure greater than 20 Torr and power delivered into the plasma core at a density of greater than 50 W cm⁻³. To achieve the highest rates, power delivered into the plasma core may exceed 100 W cm⁻³ and pressures may exceed 100 Torr, resulting in a gas temperature in the plasma core that may exceed 3000 C. In order to achieve relatively high growth rate diamond deposition, lower power densities into the plasma and lower pressures may also give adequate process results.

The plasma discharge for CVD diamond growth may be generated in several different ways. Typically, microwave power sources operate at either 2.45 GHz or at 915 MHz in frequency, and at power levels as low as 1 kW to greater than 100 kW. Operating at microwave frequencies is attractive because the energy travels in a wave and the geometry of the process chamber is configured to allow the discharge to be centered near the substrate where the deposition occurs, and away from the process chamber walls. This feature improves efficiency and reduces contamination from wall surfaces. Other microwave frequencies can be used but these two are most commonly used as these frequencies are reserved for industrial applications by international agreement and components are widely available commercially.

More recently, other frequencies for the power source and other techniques for coupling the power to the plasma discharge have been developed that are suitable for CVD diamond growth. One such technique is a toroidal plasma discharge in which RF power at 400 kHz is inductively coupled through a transformer structure into a closed-loop discharge. See, for example, U.S. Patent No. 10,443,150, entitled “Toroidal Plasma Processing Apparatus with a Shaped Workpiece Holder”, and U.S. Pat. No. 9,909,215, entitled “Toroidal Plasma Processing Apparatus”, which are both assigned to the present assignee. Other RF frequencies may be utilized in the toroidal discharge as well, from as low as 20 kHz to over 14 MHz. Another example is that of using a direct current (DC) discharge as the plasma source in a CVD diamond system. Other types of RF discharges may also be used.

A typical plasma chemical vapor deposition system for growth of diamond material will have the following functional elements: (1) gas delivery system; (2) power system for plasma generation; (3) process chamber and its components; and (4) computer and control electronics that allows the various functions of the CVD system to be controlled and automated and data to be analyzed and stored. The gas delivery system allows the various process gases to be introduced into the process chamber and typically includes a set of mass flow controllers, each of which controls one or more specific gases. The power system for plasma generation is typically a microwave power supply that typically operates at 2.45 GHz or 915 MHz or a radio-frequency system that typically operates at 20 kHz to greater than 14 MHz but can also be a direct-current system.

The process chamber includes a vacuum chamber containing a temperature-controlled stage on which the seed is placed. The process chamber is typically equipped with viewports, which allows the use of optical diagnostics. There also may be a vacuum throttle valve for controlling chamber pressure and various vacuum gauging and controls. In one particular configuration, the stage is cooled by circulating water or other fluid. Also, an intermediate element, such as molybdenum, tungsten, or another refractory metal, may be placed on the cooled stage and configured to receive the seed.

Substrate holders constructed of molybdenum, tungsten or other refractory metals are often used. Other materials are possible as well including aluminum oxide, aluminum nitride, silicon carbide, other ceramics, silicon. Metals such as copper and stainless steel may also be used in some applications. Polycrystalline diamond substrate holders may also be used. For some applications the geometry of the substrate holder is optimized for temperature uniformity to match the plasma discharge shape, thermal characteristics and chemistry. See, for example, U.S. patent application Ser. No. 17/424,081, entitled “Method of Growing Single Crystal Diamond Assisted by Polycrystalline Diamond Growth”. In some systems, the substrate holder has a flat plate that includes cooling capability. In other systems, the substrate holder includes elements that provide shielding of the samples from the plasma discharge, while allowing the sample to be at the desired temperature and the reactive gas species to reach the sample surface.

A vacuum throttle valve is often used to control the pressure in the vacuum chamber independently of the mass flow controllers setting the rate at which the various gases flow into the system. The vacuum pump is a mechanical device that pumps the gases out of the vacuum system.

For some applications, it may be desirable to grow a thin film of diamond material on the outside of a diamond piece that is in its finished or near-finished condition. There are numerous examples of such applications in the area of diamond electronics, sensors and quantum devices, where the thin film may have electronic, physical or optical properties that are different relative to the starting piece of diamond. Any of the techniques used to grow diamond, such as the CVD, HPHT and HF methods can be used to grow the thin film of diamond on the outside of the initial piece.

Recently, there has been some interest in growing thin films of diamond on the surface of diamond gems that are in their finished or near-finished state. Growing such thin films is desirable for many reasons. One reason is that the thin film can provide different optical properties with respect to the underlying gem in order to change its color or to repair defects in the surface of the gem.

Another reason for growing thin films of diamond on the surface of diamond gems is to personalize the diamond. One way of personalizing the diamond is to include carbon from a human or an animal or an inanimate object in the growth process. In some embodiments, this is achieved by using a gas delivery system in a CVD diamond growth system that allows a process gas that includes carbon sources from the living or deceased human, animal, or inanimate object to be introduced into the process chamber. Such a finished diamond gem would then have sentimental value to the owner and/or to the person providing the carbon material. There is considerable market interest in custom jewelry that has some personal relationship to a family member or loved one including pets. Thus, one aspect of the present teaching is growing a layer of diamond material on the surface of a finished or unfinished diamond sample, where the thin film is comprised of carbon at least in part derived from one or more deceased or living animals or humans or inanimate objects.

There are known methods of deriving carbon from cremated remains of humans or animals or inanimate objects to create diamond gems using high pressure, high temperature diamond growth processes. However, these processes do not coat existing finished or partly finished diamonds with a thin film comprised of the carbon derived from humans or animals or inanimate objects. Instead, these processes start with a very small diamond seed. Consequently, with these processes, it is common for the entire process, beginning from obtaining samples of the carbon-containing material to generating the required carbon to completing the finished gem, to take many months to complete. The process is also limiting in that large size diamond gems, that is those greater than about 1.5 carat in weight, are particularly difficult to make resulting in high costs which greatly limits their market.

Carbon-containing material can be obtained from live humans or animals, in the form of hair or skin or other types of tissue samples. Carbon-containing material can also be obtained from deceased humans or animals. Carbon derived from multiple humans or animals can also be used in the growth process. As an example, samples containing carbon from multiple family members, multiple pets, or humans with pets may be used to give consumers many options for personalizing they gem. Carbon can also be derived from inanimate objects such as trees, plants, dirt, automobiles, houses and many other objects that may represent something of value to a consumer.

As an alternative, remains from deceased humans or animals which have been cremated can be used as a source of carbon. The ashes resulting from cremation often contain carbon predominately in the form of calcium carbonate. In order to use cremation ashes in a CVD diamond growth process, the carbon needs to be removed from the calcium carbonate and transformed into a gas. The calcium carbonate can be chemically processed prior to use in the growth system.

Alternatively, the atomic hydrogen generated in the CVD growth chamber may itself be used to form methane or other hydrocarbon gas necessary for the CVD diamond growth.

The starting diamond material for CVD diamond growth can be in the form of a finished or near-finished diamond gem. In that case, the film grown on it may be quite thin, that is from as little as a few microns to as much as several millimeters thick. Alternatively, the starting material for the CVD diamond growth can be in the form of a rough cut diamond gem, in which case the film grown on it must be much thicker, that is on order of 0.2 mm or greater. Sufficient material must be grown to allow some to remain after the gem is finished to its final shape.

It is also possible to start with an existing polished diamond gem of a size that much larger than one carat in weight. This would allow shapes and sizes of gems that are well beyond typical HPHT diamonds grown from carbon obtained from live or deceased humans, pets or other animals. This also allows the size and shape of the diamond to be selected in advance and the process completed in a time frame that would be much shorter than any known high temperature, high pressure diamond growth process.

After the film comprising carbon from either deceased or live human or animal is grown using CVD growth process, the sample is removed from the growth chamber and is finished to a final state. This is typically in the shape of a finished diamond gem. However, in some markets, a flat plate or other shape may be preferred. The diamond material needs to be grown to a thickness great enough so that the finishing process can be polished to completion so that a significant portion remains of the film comprising carbon from either deceased or live human, animal, or inanimate objects.

Both commonly used methods for growing diamond, the HPHT method and the CVD method, initiate the growth process for single crystal diamond with a diamond seed. The seed used for these processes is often formed using the same CVD or HPHT process. However, at some prior point in time, the very first seed used in both HPHT and CVD growth came from a mined naturally formed diamond. Single crystal diamond material has also been grown on non-single crystal diamond substrates, such as iridium. For growth of polycrystalline diamond material, in addition to single crystal substrates, there is a wide choice of non-single-crystal substrates including silicon, molybdenum, tungsten, and many other materials. In any event, diamond and diamond like material can be traced back to particular seed materials.

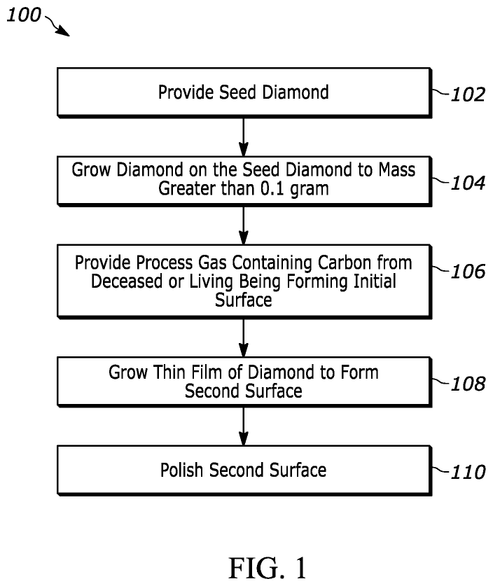

FIG. 1 illustrates a flow chart 100 of a method of growing personalized diamond gems by chemical vapor deposition. In a first step 102, a seed diamond material is provided. In some method the seed diamond is provided from a particular geographic location. Also, in some methods, the seed diamond provided has a mass of at least 0.05 gram.

In a second step 104, diamond is grown on the seed diamond material to a mass of greater than 0.1 gram with an initial finished surface. In some methods, the diamond is grown to a thickness greater than one millimeter thick. In some methods, the diamond is grown by high pressure high temperature method. In other methods, the diamond is grown by chemical vapor deposition. In yet other methods, the diamond is grown by a hot filament method.

In a third step 106, a process gas is provided that contains at least some carbon from a deceased or living being or inanimate object. In some methods, the process gas was derived from cremated remains of the deceased being. In some methods, the process gas was derived from calcium carbonate. In some methods, the process gas was derived from carbon from more than one deceased or living being and, in one particular method, derived from more than one human family member. In yet other methods, the process gas can contain at least some carbon from hair that has not been cremated and/or from skin that has not been cremated. In other methods, the process gas can contain carbon from inanimate objects.

In a fourth step 108, a thin film of diamond is grown on top of the initial finished surface to form a second finished surface by using chemical vapor deposition with the process gas or by some other means. In some methods, the growing the thin film of diamond on top of the initial finished surface comprises growing the thin film to a thickness of less than 10 microns thick. In other methods, the growing the thin film of diamond on top of the initial finished surface comprises growing the thin film to a thickness of greater than 0.1 mm thick. In other methods, the growing the thin film of diamond on top of the initial finished surface comprises growing the thin film to a thickness of greater than one millimeter thick. In other methods, the growing the thin film of diamond on top of the initial finished surface comprises growing the thin film to a mass of greater than 0.1 gram or to a mass of greater than 0.2 gram or to a mass of greater than 1.0 gram.

In some methods, the growing the thin film of diamond on top of the initial finished surface comprises growing the thin film to a thickness great enough so that the diamond can be polished. In various embodiments, the growing the thin film of diamond on top of the initial finished surface to form the second finished surface can be performed to repair the second finished surface.

In an optional fifth step 110, the second finished surface is polished. In various embodiments, the second finished surface can provide a color to the diamond or to change other optical properties of the diamond.

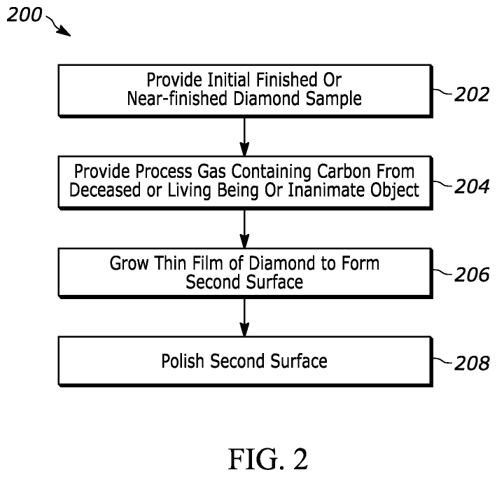

FIG. 2 illustrates a flow chart 200 of another method of growing personalized diamond gems by chemical vapor deposition. In a first step 202, an initial single crystal diamond sample in its finished or near-finished state is provided. The initial single crystal diamond sample may be obtained from mining or it may be lab-grown. In some methods, the initial diamond sample is provided from a particular geographic location. Also, in some methods, the seed diamond provided has a mass of at least 0.05 gram.

In a second step 104, a process gas is provided that contains at least some carbon from a deceased or living being or inanimate object. In some methods, the process gas was derived from cremated remains of the deceased being. In some methods, the process gas was derived from calcium carbonate. In some methods, the process gas was derived from carbon from more than one deceased or living being and, in one particular method, derived from more than one human family member. In yet other methods, the process gas contains at least some carbon from hair that has not been cremated and/or from skin that has not been cremated. In yet other methods, the process gas can contain carbon from inanimate objects.

In a third step 206, a thin film of diamond is grown on top of the initial finished surface to form a second finished surface by using chemical vapor deposition with the process gas or by some other means, such as HPHT and HF. In some methods, the growing the thin film of diamond on top of the initial finished surface comprises growing the thin film to a thickness of less than 10 microns thick. In other methods, the growing the thin film of diamond on top of the initial finished surface comprises growing the thin film to a thickness of greater than 0.1 mm thick. In other methods, the growing the thin film of diamond on top of the initial finished surface comprises growing the thin film to a thickness of greater than one millimeter thick. In other methods, the growing the thin film of diamond on top of the initial finished surface comprises growing the thin film to a mass of greater than 0.1 gram, or to a mass of greater than 0.2 gram, or to a mass of greater than 1.0 gram.

In some methods, the growing the thin film of diamond on top of the initial finished surface comprises growing the thin film to a thickness great enough so that the diamond can be polished. In various embodiments, the growing the thin film of diamond on top of the initial finished surface to form the second finished surface can be performed to repair the second finished surface.

In an optional fourth step 208, the second finished surface is polished. In various embodiments, the second finished surface can provide a color to the diamond or to change other optical properties of the diamond.

The methods of the present teaching can be used to produce diamond suitable for many different consumer markets. For example, there is considerable market interest in understanding the full geographic genealogy of lab-grown diamond material used for jewelry. In particular, there is great interest in knowing the origin of the very first diamond seed that was used to make subsequent diamond seeds that are associated with the diamond seed that is used to grow a particular diamond even though it may be many generations of growth distant from current material. For example, many consumers do not want to own diamond associated with diamonds mined in conflict countries. Many consumers also want diamonds associated particular countries or regions.

In particular, many jewelry consumers desire diamond that is only associated with diamonds mined in the United States. However, there are very few potential locations in the United States where suitable mined diamond material can be obtained. Fortunately, only one or a few seeds derived from mined diamonds are needed in order to create a viable ongoing supply of diamond seeds for growing diamond by CVD or HPHT methods. So even if the seed diamond is rare and expensive, the cost can be amortized over many individual lab-grown diamonds. One feature of the present teaching is the ability to know and track the provenance of a seed diamond used in a finished CVD- or HPHT-grown-diamond element.

Another way of personalizing lab-grown diamond for some consumer markets is by providing a geographic lineage to the consumer. Yet another way is to personalize the geographic lineage of the lab-grown diamond gemstone for a particular consumer's desire. A feature of the present teaching is the ability to know and track the geography associated with a seed diamond used in a finished CVD- or HPHT-grown-diamond product. To date, manufacturers, however, have not capitalized on the many marketing advantages of selling product as being entirely sourced in particular locations, such as in the United States. Educating the customer that lab-grown diamonds can trace their origin to a particular mined diamond or, at least to a particular geographical location, could significantly benefit the marketing and value proposition of a lab-grown diamond verses mined diamonds. To date, no known lab-grown manufacturer describes tracing diamond products back to the physical origin of their seed in their marketing.

Thus, another aspect of the present teaching is the characterization of lab grown diamond by a geographic lineage so that lab grown diamond can be positively defined by a particular location in order to further personalize the diamond gem or other lab-grown diamond product.

### EQUIVALENTS

While the Applicants' teaching is described in conjunction with various embodiments, it is not intended that the Applicants' teaching be limited to such embodiments. On the contrary, the Applicants' teaching encompasses various alternatives, modifications, and equivalents, as will be appreciated by those of skill in the art, which may be made therein without departing from the spirit and scope of the teaching.

What is claimed is:

1. A method of growing personalized single crystal diamond, the method comprising:
a) providing a seed diamond material;
b) growing diamond on the seed diamond material to a mass of greater than 0.1 gram with an initial finished surface;
c) providing a process gas that contains at least some carbon from a deceased or living being; and
d) growing a thin film of diamond on top of the initial finished surface to form a second finished surface by using chemical vapor deposition with the process gas.

2. The method of claim 1 wherein the providing the seed diamond material comprises selecting a seed diamond material from a particular geographic location.

3. The method of claim 1 wherein the growing diamond on the seed diamond comprises growing diamond by a high pressure high temperature method.

4. The method of claim 1 wherein the growing diamond on the seed diamond comprises growing diamond by a chemical vapor deposition method.

5. The method of claim 1 wherein the growing diamond on the seed diamond comprises growing diamond by a hot filament method.

6. The method of claim 1 wherein the providing the process gas that contains at least some carbon from the deceased or living being comprises deriving the carbon from cremated remains of a deceased being.

7. The method of claim 1 wherein the providing the process gas comprises processing calcium carbonate.

8. The method of claim 1 wherein the growing the thin film of diamond on top of the initial finished surface comprises growing the thin film to a thickness of less than 10 microns thick.

9. The method of claim 1 wherein the growing the thin film of diamond on top of the initial finished surface comprises growing the thin film to a thickness of greater than 0.1 millimeter thick.

10. The method of claim 1 wherein the growing the thin film of diamond on top of the initial finished surface comprises growing the thin film to a thickness of greater than 1.0 millimeter thick.

11. The method of claim 1 wherein the providing the process gas that contains at least some carbon from the deceased or living being comprises deriving the carbon from more than one deceased or living being.

12. The method of claim 1 wherein the providing the process gas that contains at least some carbon from the deceased or living being comprises deriving the carbon from more than human family member.

13. The method of claim 1 wherein the providing the process gas that contains at least some carbon from the deceased or living being comprises deriving the carbon from hair that has not been cremated.

14. The method of claim 1 wherein the providing the process gas that contains at least some carbon from the deceased or living being comprises deriving the carbon from skin that has not been cremated.

15. The method of claim 1 wherein the providing the process gas that contains at least some carbon from the deceased or living being comprises deriving the carbon from tissue.

16. The method of claim 1 further comprising polishing the second finished surface.

17. The method of claim 1 wherein the growing the thin film of diamond on top of the initial finished surface to form the second finished surface is performed to change the color of the diamond.

18. The method of claim 1 wherein the growing the thin film of diamond on top of the initial finished surface to form the second finished surface is performed to change the optical properties of the diamond.

19. The method of claim 1 wherein the growing the thin film of diamond on top of the initial finished surface to form the second finished surface is performed to repair the second finished surface.

20. The method of claim 1 wherein the growing the thin film of diamond on top of the initial finished surface to form the second finished surface comprises growing the diamond to a thickness great enough so that the diamond can be polished.
